(19) United States
(12) Patent Application Publication
(10) Pub. No.: US 2026/0132707 A1
(43) Pub. Date: May 14, 2026

(54) RESERVOIR MODELING AND WELL PLACEMENT USING MACHINE LEARNING

(71) Applicant: Schlumberger Technology Corporation, Sugar Land, TX (US)

(72) Inventors: Hussein Mustapha, Abu Dhabi (AE); Shi Su, Abingdon (GB); Samat Ramatullayev, Abu Dhabi (AE)

(21) Appl. No.: 19/437,474

(22) Filed: Dec. 31, 2025

Related U.S. Application Data
(63) Continuation-in-part of application No. 18/264,193.
(60) Provisional application No. 63/199,968, filed on Feb. 5, 2021.
(60) Provisional application No. 63/199,958, filed on Feb. 5, 2021.
(60) Provisional application No. 63/199,957, filed on Feb. 5, 2021.
(60) Provisional application No. 63/200,063, filed on Feb. 12, 2021.

(51) Int. Cl. E21B 43/30; E21B 44/00; E21B 49/00; G01V 20/00; G06F 30/27

(52) U.S. Cl. CPC E21B 43/30; E21B 44/00; E21B 49/00; G01V 20/00; G06F 30/27; E21B 2200/20; E21B 2200/22

(57) ABSTRACT

A method for predicting petrophysical properties of a three-dimensional (3D) volume includes receiving input data related to the 3D volume. The method includes determining a clustering scheme for the input data based on the input data, clustering the input data based on the clustering scheme to generate a plurality of clusters, and associating the plurality of clusters with a plurality of CRTs based on the input data. The method also includes generating predicted training sets for the petrophysical properties based on the clustering of the input data, the plurality of CRTs, or a combination thereof, selecting a representative predicted training set from the predicted training sets based on the input data, generating a model based on the representative predicted training set, and predicting the petrophysical properties of the 3D volume based on the model.

### CROSS-REFERENCE TO RELATED APPLICATIONS

This application claims priority to U.S. Provisional Patent Application Ser. No. 63/199,957, which was filed on Feb. 5, 2021, U.S. Provisional Patent Application Ser. No. 63/199,958, which was filed on Feb. 5, 2021, U.S. Provisional Patent Application Ser. No. 63/199,968 which was filed on Feb. 5, 2021, U.S. Provisional Patent Application Ser. No. 63/200,063 which was filed on Feb. 12, 2021, and is also a Continuation-In-Part of U.S. patent application Ser. No. 18/264,193, which was filed on Aug. 3, 2023. Each of these applications is incorporated herein by reference in its entirety.

### BACKGROUND

In conventional systems, several workflows include calibrating model parameters to select a model that accurately represents data. For instance, history matching is a process of calibrating reservoir uncertainty parameters with an objective of obtaining simulation production data as close as possible to historical data. The process is time-consuming and requires heavy computations, which pose a bottleneck for further steps in a reservoir modeling workflow.

Further, once one or more models are selected, the models may be used to design wells, drilling parameters, production plans, etc. However, given the number of models that may be simulated in order to accurately represent the reservoir, the number of potential locations for the wells, and the number of different design parameters for a well at a given location, the process of using the wells to provide useful information can take a large amount of time, expensive or potentially unavailable processing power, or both. Thus, in addition to streamlining the reservoir modeling process, systems and methods for more efficiently implementing the models to provide useful insights, e.g., for well placement analysis, would be a welcome addition.

### SUMMARY

A method for predicting one or more petrophysical properties of a three-dimensional (3D) volume is disclosed. The method includes receiving input data related to the 3D volume. The method also includes determining a clustering scheme for the input data. The method also includes clustering the input data based on the clustering scheme to generate a plurality of clusters. The method also includes associating the plurality of clusters with a plurality of candidate rock types (CRTs). The method also includes generating one or more predicted training sets for the one or more petrophysical properties based on the plurality of CRTs. The method also includes selecting a representative predicted training set from the one or more predicted training sets. The method also includes generating a model based on the representative predicted training set. The method also includes predicting the one or more petrophysical properties of the 3D volume based on the model.

A computing system is also disclosed. The computing system includes one or more processors and a method system. The method system includes one or more non-transitory computer-readable media storing instructions that, when executed by at least one of the one or more processors, cause the computing system to perform operations for predicting one or more petrophysical properties of a three-dimensional (3D) volume. The operations include receiving input data related to the 3D volume. The input data includes a training set obtained from a plurality of inputs. The training set includes training values. The operations also include determining a clustering scheme for the input data based on the input data. The clustering scheme includes an unsupervised clustering scheme. The operations also include clustering the input data based on the clustering scheme to generate a plurality of clusters. Each cluster of the plurality of clusters represents a respective petrophysical group of one or more petrophysical groups. The operations also include associating each cluster of the plurality of clusters with a respective candidate rock type (CRT) of a plurality of candidate rock types (CRTs) based on the input data. The operations also include generating one or more predicted training sets for the one or more petrophysical properties based on the clustering of the input data, the plurality of CRTs, or a combination thereof. The operations also include selecting a representative predicted training set from the one or more predicted training sets based on the input data. The operations also include generating a model based on the representative predicted training set. The operations also include predicting the one or more petrophysical properties of the 3D volume based on the model.

A non-transitory computer-readable medium is also disclosed. The medium stores instructions that, when executed by one or more processors of a computing system, cause the computing system to perform operations for predicting one or more petrophysical properties of a three-dimensional (3D) volume. The operations include receiving input data related to the 3D volume. The input data includes a training set obtained from a plurality of inputs. The training set includes training values. The operations also include determining a clustering scheme for the input data based on the input data. The clustering scheme includes an unsupervised clustering scheme. Determining the clustering scheme comprises determining a number of clusters based on the training set. The operations also include clustering the input data based on the clustering scheme to generate a plurality of clusters. Each cluster of the plurality of clusters represents a respective petrophysical group of one or more petrophysical groups. The operations also include associating each cluster of the plurality of clusters with a respective candidate rock type (CRT) of a plurality of candidate rock types (CRTs) based on the input data. The operations also include generating one or more predicted training sets for the one or more petrophysical properties based on the clustering of the input data, the plurality of CRTs, or a combination thereof. The operations also include selecting a representative predicted training set from the one or more predicted training sets based on the input data. The operations also include generating a model based on the representative predicted training set. The operations also include predicting the one or more petrophysical properties of the 3D volume based on the model.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIGS. 1A, 1B, 1C, 1D, 2, 3A, and 3B illustrate simplified, schematic views of an oilfield and its operation, according to an embodiment.

FIG. 4 illustrates a workflow for assisted history matching through optimization and machine learning, according to an embodiment.

FIG. 5 illustrates an example workflow for training a proxy machine learning model, according to an embodiment.

FIG. 6 is an example workflow in which the proxy machine learning model is used as a black box to reduce time and computations that would otherwise be required by an actual simulator, according to an embodiment.

FIG. 7 illustrates a detailed view of an optimization workflow, according to an embodiment.

FIG. 8 illustrates a flowchart of a method for selecting a classified subset of representative observations, according to an embodiment.

FIG. 9 illustrates an example of one type of clustering that may be used, showing a flowchart of a method for building a machine learning model to perform clustering.

FIG. 10 illustrates a flowchart of a method for drilling a well, e.g., based on a selection of a location for the well, according to an embodiment.

FIG. 11 illustrates an exemplary workflow for simultaneous classification and prediction of petrophysical properties in a 3D space, according to an embodiment.

FIG. 12 illustrates an exemplary machine-learning driven workflow for rocky typing and permeability prediction, according to an embodiment.

FIG. 13 illustrates a flowchart of a method for predicting one or more petrophysical properties of a three-dimensional (3D) volume, according to an embodiment.

FIG. 14 illustrates a schematic view of a computing system for performing at least a portion of the method(s) described herein, according to an embodiment.

### DESCRIPTION OF EMBODIMENTS

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object could be termed a second object, and, similarly, a second object could be termed a first object, without departing from the scope of the invention. The first object and the second object are both objects, respectively, but they are not to be considered the same object.

The terminology used in the description of the invention herein is for the purpose of describing particular embodiments only and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques and workflows that are in accordance with some embodiments. Some operations in the processing procedures, methods, techniques and workflows disclosed herein may be combined and/or the order of some operations may be changed. The illustrations presented herein are in the context of oilfield operations. However, it will be appreciated that embodiments of the present disclosure may be readily tailored for use in other applications in which characterization of the subsurface is helpful. For example, building structures, such as wind farms and solar arrays, may employ such subsurface characterization efforts. Likewise, geothermal applications may employ embodiments of the present applications.

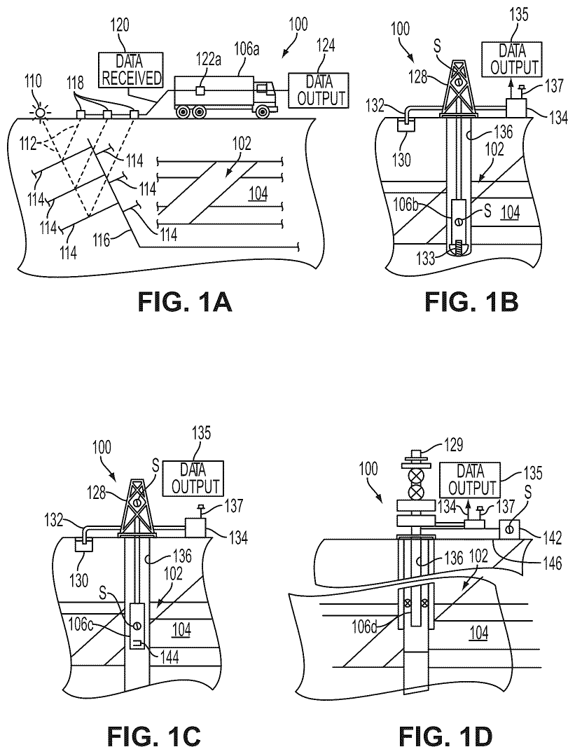

FIGS. 1A-1D illustrate simplified, schematic views of oilfield 100 having subterranean formation 102 containing reservoir 104 therein in accordance with implementations of various technologies and techniques described herein. FIG. 1A illustrates a survey operation being performed by a survey tool, such as seismic truck 106a, to measure properties of the subterranean formation. The survey operation is a seismic survey operation for producing sound vibrations. In FIG. 1A, one such sound vibration, e.g., sound vibration 112 generated by source 110, reflects off horizons 114 in earth formation 116. A set of sound vibrations is received by sensors, such as geophone-receivers 118, situated on the earth's surface. The data received 120 is provided as input data to a computer 122a of a seismic truck 106a, and responsive to the input data, computer 122a generates seismic data output 124. This seismic data output may be stored, transmitted or further processed as desired, for example, by data reduction.

FIG. 1B illustrates a drilling operation being performed by drilling tools 106b suspended by rig 128 and advanced into subterranean formations 102 to form wellbore 136. Mud pit 130 is used to draw drilling mud into the drilling tools via flow line 132 for circulating drilling mud down through the drilling tools, then up wellbore 136 and back to the surface. The drilling mud is typically filtered and returned to the mud pit. A circulating system may be used for storing, controlling, or filtering the flowing drilling mud. The drilling tools are advanced into subterranean formations 102 to reach reservoir 104. Each well may target one or more reservoirs. The drilling tools are adapted for measuring downhole properties using logging while drilling tools. The logging while drilling tools may also be adapted for taking core sample 133 as shown.

Computer facilities may be positioned at various locations about the oilfield 100 (e.g., the surface unit 134) and/or at remote locations. Surface unit 134 may be used to communicate with the drilling tools and/or offsite operations, as well as with other surface or downhole sensors. Surface unit 134 is capable of communicating with the drilling tools to send commands to the drilling tools, and to receive data therefrom. Surface unit 134 may also collect data generated during the drilling operation and produce data output 135, which may then be stored or transmitted.

Sensors (S), such as gauges, may be positioned about oilfield 100 to collect data relating to various oilfield operations as described previously. As shown, sensor (S) is positioned in one or more locations in the drilling tools and/or at rig 128 to measure drilling parameters, such as weight on bit, torque on bit, pressures, temperatures, flow rates, compositions, rotary speed, and/or other parameters of the field operation. Sensors (S) may also be positioned in one or more locations in the circulating system.

Drilling tools 106b may include a bottom hole assembly (BHA) (not shown), generally referenced, near the drill bit (e.g., within several drill collar lengths from the drill bit). The bottom hole assembly includes capabilities for measuring, processing, and storing information, as well as communicating with surface unit 134. The bottom hole assembly further includes drill collars for performing various other measurement functions.

The bottom hole assembly may include a communication subassembly that communicates with surface unit 134. The communication subassembly is adapted to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

Typically, the wellbore is drilled according to a drilling plan that is established prior to drilling. The drilling plan typically sets forth equipment, pressures, trajectories and/or other parameters that define the drilling process for the wellsite. The drilling operation may then be performed according to the drilling plan. However, as information is gathered, the drilling operation may need to deviate from the drilling plan. Additionally, as drilling or other operations are performed, the subsurface conditions may change. The earth model may also need adjustment as new information is collected

The data gathered by sensors (S) may be collected by surface unit 134 and/or other data collection sources for analysis or other processing. The data collected by sensors (S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 134 may include transceiver 137 to allow communications between surface unit 134 and various portions of the oilfield 100 or other locations. Surface unit 134 may also be provided with or functionally connected to one or more controllers (not shown) for actuating mechanisms at oilfield 100. Surface unit 134 may then send command signals to oilfield 100 in response to data received. Surface unit 134 may receive commands via transceiver 137 or may itself execute commands to the controller. A processor may be provided to analyze the data (locally or remotely), make the decisions and/or actuate the controller. In this manner, oilfield 100 may be selectively adjusted based on the data collected. This technique may be used to optimize (or improve) portions of the field operation, such as controlling drilling, weight on bit, pump rates, or other parameters. These adjustments may be made automatically based on computer protocol, and/or manually by an operator. In some cases, well plans may be adjusted to select optimum (or improved) operating conditions, or to avoid problems.

FIG. 1C illustrates a wireline operation being performed by wireline tool 106c suspended by rig 128 and into wellbore 136 of FIG. 1B. Wireline tool 106c is adapted for deployment into wellbore 136 for generating well logs, performing downhole tests and/or collecting samples. Wireline tool 106c may be used to provide another method and apparatus for performing a seismic survey operation. Wireline tool 106c may, for example, have an explosive, radioactive, electrical, or acoustic energy source 144 that sends and/or receives electrical signals to surrounding subterranean formations 102 and fluids therein.

Wireline tool 106c may be operatively connected to, for example, geophones 118 and a computer 122a of a seismic truck 106a of FIG. 1A. Wireline tool 106 may also provide data to surface unit 134. Surface unit 134 may collect data generated during the wireline operation and may produce data output 135 that may be stored or transmitted. Wireline tool 106c may be positioned at various depths in the wellbore 136 to provide a survey or other information relating to the subterranean formation 102.

Sensors (S), such as gauges, may be positioned about oilfield 100 to collect data relating to various field operations as described previously. As shown, sensor S is positioned in wireline tool 106c to measure downhole parameters which relate to, for example porosity, permeability, fluid composition and/or other parameters of the field operation.

FIG. 1D illustrates a production operation being performed by production tool 106d deployed from a production unit or Christmas tree 129 and into completed wellbore 136 for drawing fluid from the downhole reservoirs into surface facilities 142. The fluid flows from reservoir 104 through perforations in the casing (not shown) and into production tool 106d in wellbore 136 and to surface facilities 142 via gathering network 146.

Sensors (S), such as gauges, may be positioned about oilfield 100 to collect data relating to various field operations as described previously. As shown, the sensor (S) may be positioned in production tool 106d or associated equipment, such as Christmas tree 129, gathering network 146, surface facility 142, and/or the production facility, to measure fluid parameters, such as fluid composition, flow rates, pressures, temperatures, and/or other parameters of the production operation.

Production may also include injection wells for added recovery. One or more gathering facilities may be operatively connected to one or more of the wellsites for selectively collecting downhole fluids from the wellsite(s).

While FIGS. 1B-1D illustrate tools used to measure properties of an oilfield, it will be appreciated that the tools may be used in connection with non-oilfield operations, such as gas fields, mines, aquifers, storage or other subterranean facilities. Also, while certain data acquisition tools are depicted, it will be appreciated that various measurement tools capable of sensing parameters, such as seismic two-way travel time, density, resistivity, production rate, etc., of the subterranean formation and/or its geological formations may be used. Various sensors (S) may be located at various positions along the wellbore and/or the monitoring tools to collect and/or monitor the desired data. Other sources of data may also be provided from offsite locations.

The field configurations of FIGS. 1A-1D are intended to provide a brief description of an example of a field usable with oilfield application frameworks. Part of, or the entirety, of oilfield 100 may be on land, water and/or sea. Also, while a single field measured at a single location is depicted, oilfield applications may be utilized with any combination of one or more oilfields, one or more processing facilities and one or more wellsites.

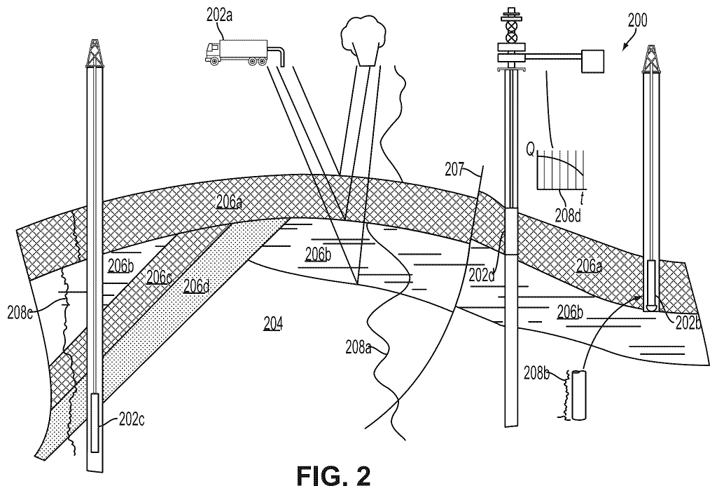

FIG. 2 illustrates a schematic view, partially in cross section of oilfield 200 having data acquisition tools 202a, 202b, 202c and 202d positioned at various locations along oilfield 200 for collecting data of subterranean formation 204 in accordance with implementations of various technologies and techniques described herein. Data acquisition tools 202a-202d may be the same as data acquisition tools 106a-106d of FIGS. 1A-1D, respectively, or others not depicted. As shown, data acquisition tools 202a-202d generate data plots or measurements 208a-208d, respectively. These data plots are depicted along oilfield 200 to demonstrate the data generated by the various operations.

Data plots 208a-208c are examples of static data plots that may be generated by data acquisition tools 202a-202c, respectively; however, it should be understood that data plots 208a-208c may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 208a is a seismic two-way response over a period of time. Static plot 208b is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 208c is a logging trace that typically provides a resistivity or other measurement of the formation at various depths.

A production decline curve or graph 208d is a dynamic data plot of the fluid flow rate over time. The production decline curve typically provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 206a-206d. As shown, this structure has several formations or layers, including a shale layer 206a, a carbonate layer 206b, a shale layer 206c and a sand layer 206d. A fault 207 extends through the shale layer 206a and the carbonate layer 206b. The static data acquisition tools are adapted to take measurements and detect characteristics of the formations.

While a specific subterranean formation with specific geological structures is depicted, it will be appreciated that oilfield 200 may contain a variety of geological structures and/or formations, sometimes having extreme complexity. In some locations, typically below the water line, fluid may occupy pore spaces of the formations. Each of the measurement devices may be used to measure properties of the formations and/or its geological features. While each acquisition tool is shown as being in specific locations in oilfield 200, it will be appreciated that one or more types of measurement may be taken at one or more locations across one or more fields or other locations for comparison and/or analysis.

The data collected from various sources, such as the data acquisition tools of FIG. 2, may then be processed and/or evaluated. Typically, seismic data displayed in static data plot 208a from data acquisition tool 202a is used by a geophysicist to determine characteristics of the subterranean formations and features. The core data shown in static plot 208b and/or log data from well log 208c are typically used by a geologist to determine various characteristics of the subterranean formation. The production data from graph 208d is typically used by the reservoir engineer to determine fluid flow reservoir characteristics. The data analyzed by the geologist, geophysicist and the reservoir engineer may be analyzed using modeling techniques.

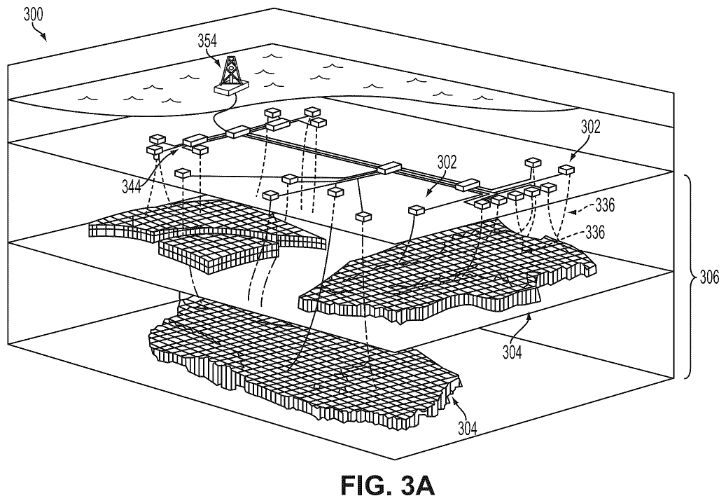

FIG. 3A illustrates an oilfield 300 for performing production operations in accordance with implementations of various technologies and techniques described herein. As shown, the oilfield has a plurality of wellsites 302 operatively connected to central processing facility 354. The oilfield configuration of FIG. 3A is not intended to limit the scope of the oilfield application system. Part, or all, of the oilfield may be on land and/or sea. Also, while a single oilfield with a single processing facility and a plurality of wellsites is depicted, any combination of one or more oilfields, one or more processing facilities and one or more wellsites may be present.

Each wellsite 302 has equipment that forms wellbore 336 into the earth. The wellbores extend through subterranean formations 306 including reservoirs 304. These reservoirs 304 contain fluids, such as hydrocarbons. The wellsites draw fluid from the reservoirs and pass them to the processing facilities via surface networks 344. The surface networks 344 have tubing and control mechanisms for controlling the flow of fluids from the wellsite to processing facility 354.

Attention is now directed to FIG. 3B, which illustrates a side view of a marine-based survey 360 of a subterranean subsurface 362 in accordance with one or more implementations of various techniques described herein. Subsurface 362 includes seafloor surface 364. Seismic sources 366 may include marine sources such as vibroseis or airguns, which may propagate seismic waves 368 (e.g., energy signals) into the Earth over an extended period of time or at a nearly instantaneous energy provided by impulsive sources. The seismic waves may be propagated by marine sources as a frequency sweep signal. For example, marine sources of the vibroseis type may initially emit a seismic wave at a low frequency (e.g., 5 Hz) and increase the seismic wave to a high frequency (e.g., 80-90Hz) over time.

The component(s) of the seismic waves 368 may be reflected and converted by seafloor surface 364 (i.e., reflector), and seismic wave reflections 370 may be received by a plurality of seismic receivers 372. Seismic receivers 372 may be disposed on a plurality of streamers (i.e., streamer array 374). The seismic receivers 372 may generate electrical signals representative of the received seismic wave reflections 370. The electrical signals may be embedded with information regarding the subsurface 362 and captured as a record of seismic data.

In one implementation, each streamer may include streamer steering devices such as a bird, a deflector, a tail buoy and the like, which are not illustrated in this application. The streamer steering devices may be used to control the position of the streamers in accordance with the techniques described herein.

In one implementation, seismic wave reflections 370 may travel upward and reach the water/air interface at the water surface 376, a portion of reflections 370 may then reflect downward again (i.e., sea-surface ghost waves 378) and be received by the plurality of seismic receivers 372. The sea-surface ghost waves 378 may be referred to as surface multiples. The point on the water surface 376 at which the wave is reflected downward is generally referred to as the downward reflection point.

The electrical signals may be transmitted to a vessel 380 via transmission cables, wireless communication or the like. The vessel 380 may then transmit the electrical signals to a data processing center. Alternatively, the vessel 380 may include an onboard computer capable of processing the electrical signals (i.e., seismic data). Those skilled in the art having the benefit of this disclosure will appreciate that this illustration is highly idealized. For instance, surveys may be of formations deep beneath the surface. The formations may typically include multiple reflectors, some of which may include dipping events, and may generate multiple reflections (including wave conversion) for receipt by the seismic receivers 372. In one implementation, the seismic data may be processed to generate a seismic image of the subsurface 362.

Marine seismic acquisition systems tow each streamer in streamer array 374 at the same depth (e.g., 5-10 m). However, marine based survey 360 may tow each streamer in streamer array 374 at different depths such that seismic data may be acquired and processed in a manner that avoids the effects of destructive interference due to sea-surface ghost waves. For instance, marine-based survey 360 of FIG. 3B illustrates eight streamers towed by vessel 380 at eight different depths. The depth of each streamer may be controlled and maintained using the birds disposed on each streamer.

### Automated Data Driven Architecture Using Machine Learning and Optimization

Artificial intelligence (AI) techniques may be used to develop machine learning (ML) based surrogate reservoir models. These models may learn from a massive amount of simulation data to unravel complex patterns between static and dynamic properties, and thus may replace a cumbersome simulation process with an intelligent and time efficient process. In some embodiments, a workflow for automated model calibration and simulation data forecasting using state-of-the-art AI techniques are disclosed. Thus, a time-consuming component in a workflow may be replaced with an intelligent ML agent which may be embedded in a holistic solution driven by optimization techniques.

In an embodiment, the workflow may be targeted for applications that include exploring a wide space of parameters with an objective of finding a best solution. The process may be cumbersome and time consuming, and may still permit uncertainty in the selection of parameters. In one embodiment, an ML proxy model may be built by utilizing deep learning for data forecasting to replace a time-consuming block in a workflow. The model may be trained from a massive amount of simulation data. This learning may be transferred to new, unseen data, thus acting as a prompt intelligence simulator. An ML surrogate model may be embedded as a black box within a fully integrated workflow to automate a history matching process. An AI solution may recommend model parameters with reduced time and computational cost.

More particularly, many applications require calibrating a set of parameters to generate a model that represents actual data. For example, the history matching process may involve exploring multiple sets of uncertainty parameters values to find the optimal solution. The procedure is time consuming and involves evaluating many realizations. For this reason, optimization workflows can be utilized to analyze the search space so that combination of uncertainty parameters may be identified rapidly. To evaluate the simulation results for each realization, an ML proxy model may be embedded in the workflow, after which the error between simulated and actual data is computed. In an embodiment, an ML surrogate model is utilized because running the simulator at each step is time consuming and costly. The solution which yields the least discrepancy between simulated and historical data may then be selected.

The developed proxy ML model may act as a black-box component where it can be used to promptly forecast the simulation results. It may perform like a simulator with immensely improved speed because of the prompt nature of ML predictions. After the optimal solution is identified using optimization, the simulation may be re-run using these parameters and the accuracy of the results may be validated.

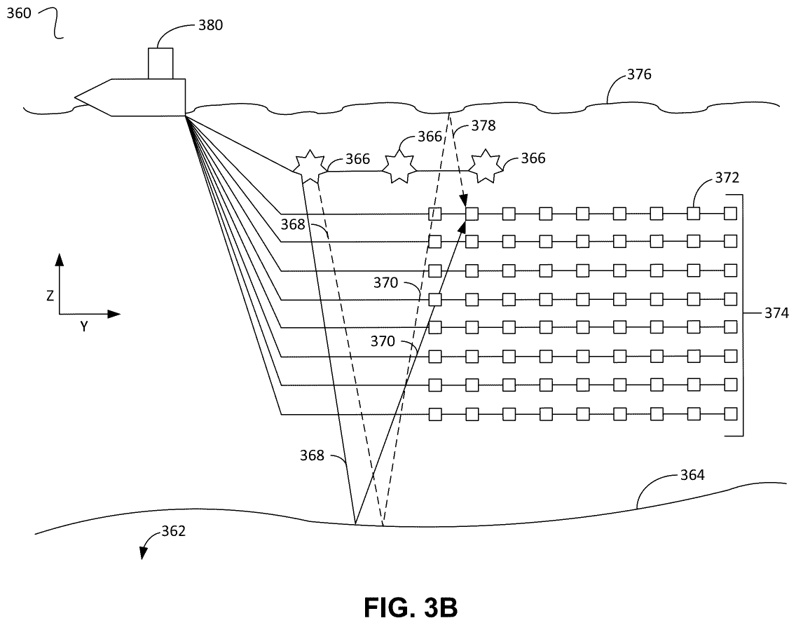

FIG. 4 illustrates an embodiment of the workflow. According to FIG. 4, a database 402 of static and dynamic data is input into optimization 404. Optimization 404 uses proxy ML model 412 having uncertainty parameters as inputs and timeseries data as output. As the term is used herein, “optimization” refers to the process of seeking parameters that suit a given application. It should not be considered to be limited to identifying the best possible parameter, but rather of executing a process that is designed to select parameters in an analytical fashion (which might or might not be the best parameters, depending on, for example, runtime, processing resources, problem description, etc.). Optimization 404 uses a proxy ML model 412 to determine uncertainty parameters 406. The uncertainty parameters 406 are provided to a simulator to produce a simulation 408 using the uncertainty parameters 406. Results of the simulation may be validated 410 by determining whether simulation results with the optimal uncertainty parameters are within an error tolerance of output of proxy machine learning model 412 using optimal uncertainty parameters 406.

Machine learning may be utilized to replace a simulator by predicting production data given a set of uncertainty parameters values. In one embodiment, the ML model may be an artificial neural network and/or a deep learning model, which tailors a timeseries nature of the data. In other embodiments, other ML models may be used.

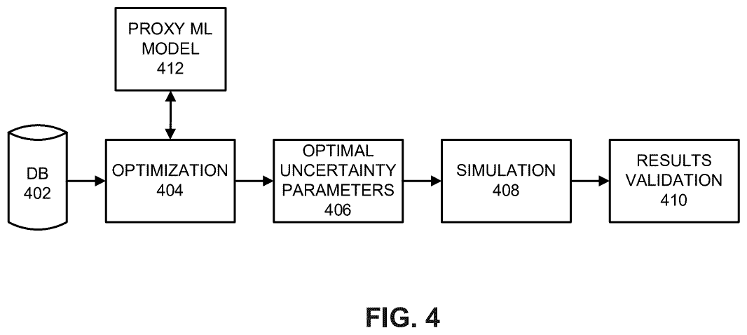

FIG. 5 shows a workflow for training a proxy ML model, e.g., to predict an output of a simulation of a physics-based model. Machine learning 504 may input training data to produce a trained proxy ML model 506. The training data may have been produced by a simulator (e.g., a simulation of a physics-based model) based on historical data. The trained proxy ML model 506 may be capable of outputting both timeseries production and injection profiles for each well in a reservoir simulation model, and different properties (e.g., time dependent pressure, saturation properties of each grids cell) of the reservoir simulation model.

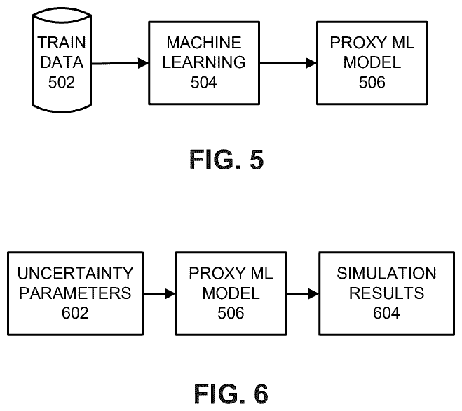

The ML proxy model, as shown in FIG. 6 may be used as a black box to reduce time and computations required by an actual simulator. According to the workflow of FIG. 6, multiple sets of uncertainty parameters 602 are provided to trained proxy ML model 506 to produce simulation results 604, which actually are predictions based on the provided sets of uncertainty parameters. As previously described, the ML proxy model may be embedded in a larger workflow acting as a simulator. The solution may be employed for different types of data and may use a best deep learning approach depending on the data type.

Optimization workflow 404 may have seek to reduce a mismatch between actual production data and simulated production data. In other words, the optimization workflow 404 attempts to find a solution including a combination of uncertainty parameters that yield a low simulation error. The optimization workflow 404 may be a minimization optimization problem in which a solution with minimal error between actual and simulation data is sought. A tolerance may be specified, which may be an upper limit for acceptable discrepancies between the actual data and simulated data.

In some embodiments, bounds constraints may be defined for each uncertainty parameter in order to limit a solutions space to feasible solutions. A workflow may start with an initial guess for a set of uncertainty parameters, which may be specified or generated randomly. An initial solution may be compared with simulation results using a same set of uncertainty parameters and an error value associated with the ML proxy model results may be computed. If the error is within the tolerance specified, the solution converges and the process may stop. However, it is uncommon to find a suitable solution from a first iteration. If the area is above the specified tolerance, the workflow may explore a new solution while taking into consideration results from a previous solution.

The new solution depends on the workflow specified and how workflow employs exploration versus exploitation approaches, among potentially other factors. The new solution may then be evaluated and the value of the objective function for the solution may again be compared with the specified tolerance. If the solution is within the specified tolerance, the workflow may halt, and a current solution is flagged as an optimal solution. Otherwise, the workflow may recursively repeat previous steps until an error tolerance is within the specified tolerance or other constraints are met, such as: a time constraint, a maximum number of iterations constraint, etc.

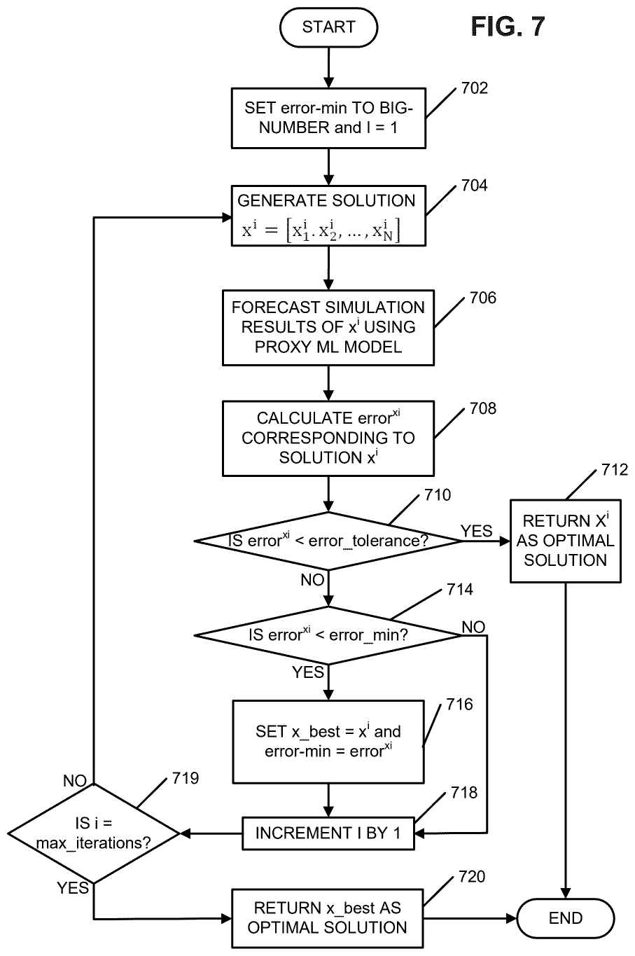

FIG. 7 is a flowchart that illustrates an embodiment of the workflow of FIG. 4 in more detail. The workflow may begin by setting error_min to a number that is larger than a possible difference between a proxy ML model output and a corresponding simulator output, and by setting an iteration counter, I, to 1 (act 702). Next, a solution, which is a set of uncertainty parameter values xⁱ, may be generated (act 704). Using the proxy ML model, simulation results of xⁱ may be forecast (act 706). An error, error^{xi}, corresponding to solution xⁱ may be calculated (act 708). Error^{xi} may be based on a difference between the forecasted simulation results using the proxy ML model and the corresponding simulation results.

Next, a determination is made regarding whether error^{xi} is less than a desired error tolerance (act 710). If so, then the workflow is halted and xⁱ is returned as an optimal solution (act 712).

If, during act 710 error^{xi} is determined not to be less than the desired error tolerance then a determination is made regarding whether error^{xi} is less than error_min (act 714). At this point, error_min is either equal to a large number or a previous value of error^{xi}. If error^{xi} is determined to be less than error_min then x_best is set to xⁱ and error^{xi} is saved to error_min (act 716).

After performing act 716 or after determining that error^{xi} is not less than error_min, iteration counter, i, may be incremented by one (act 718).

Next, a determination is made regarding whether iteration counter, i, is equal to a maximum number of iterations (act 719). If i is not equal to the maximum number of iterations, then act 704 may be performed to generate a next solution of uncertainty parameters (act 704). Otherwise, if i is equal to the maximum number of iterations, then the solution saved at x_best may be returned as an optimal solution.

The workflow shown in FIG. 7 is one example of a workflow, many other different workflows may be used in other embodiments.

In some embodiments, tools and supported workflow steps may be clearly separated based on capability to achieve a maximum degree of performance scalability. Further, (1) geomodeling and simulation tools may be used for generating model output data; (2) based on decision objectives, multi-objective model responses may be extracted and/or calculated from model output data (time or depth dependent, spatial, etc.); (3) analytics may be applied to processed response data for automatic interpretation and result analysis; and (4) automatic predictive modeling may be used to generate history matching candidates.

Multi-objective response values included in analytics and ML workflows may correlate with a definition of a calibrated model. Automatic data selection and processing mechanisms may be used to extract a few representative data points from model output data for data analysis. In some embodiments, the processing described with respect to FIG. 7 may be performed in a cloud using, for example, agile reservoir modeling (ARM) such that thousands of simulations with different uncertainty parameter values may be executed simultaneously. The optimal set of results (e.g., reservoir models matching historical actual reservoir performance) obtained using the above-described method can be fed in Model Selection System and/or Well Placement Selection Under Uncertainty methods.

### Model Selection System

One of more of the calibrated models may be employed in an uncertainty analysis, e.g., to produce and evaluate multiple different model realizations. Uncertainty is prevalent in reservoir characterization studies. In order to make business decisions, companies may execute studies where a model is built to describe the behavior of the reservoir. Impacting parameters are identified, along with their probability distributions. These impacting parameters may be reservoir parameters (e.g., porosity, permeability, structure, rock quality), economical (e.g., oil price), combinations thereof, or otherwise. These parameters may be derived from raw, measured data.

A set of these parameters define a probable model, also referred to as a model “realization”, e.g., models of a same subsurface volume (e.g., reservoir) but with different parameters based on probability and matching the actual historical production data. A given realization can then go through one or more numerical experiments, after which outputs are obtained (also referred to as “responses”). These may be referred to as performance key performance indicators (KPIs) which are directly or indirectly related to decision making criteria. Examples of KPIs include ultimate recovery, volumes in place,, potential production and injection rates and economic metrics (e.g., net present value).

It is understood that sampling the distribution of the input parameters that are matching historical actual production data can lead to a large number of realizations, which are equiprobable. Given realistic constraints on processing capabilities, even leveraging “cloud” computing resources, it is impractical to perform and analyze so many numerical experiments. Thus, the impact of a given parameter on the responses may be incorrectly estimated due to the difficulty in exploring the existing uncertainty variables in later stages of the study. Users thus may choose a deterministic approach, and/or may be scenarios chosen manually, without a systematic consideration of the responses that impact decision making.

The combination of different analysis and methodologies can allow one to reduce the number of models needed to be assessed to still obtain accurate responses. This enables the study to explore many more scenarios and possibilities, enriching the decision-making process.

In an embodiment, an application that can read from a database of different observations (e.g. model realizations of a particular reservoir along with their inputs—such as porosity, permeability, rock types, and responses—such as timeseries production and injection profiles for all wells, in-place volume, recovery), and, based on data analysis via a conjunction of visualizations, machine learning and artificial intelligence methods, automatically selects a classified subset of representative observations containing, in some embodiments, the least amount necessary to properly characterize the behavior (e.g., cumulative distribution function) of one or more selected meaningful responses. Furthermore, the application enables the user to enter input parameters pertaining to a specific reservoir realization and obtain a prediction of the behavior of the trained responses.

Current workflows focus on the overall integrated workflow, and not specifically on the model selection. Therefore, although some workflows may present functionality that allows for a manual, guided selection practice, there is a need, under a single system, for a unified workflow that provides: sensitivity on the impact of input variables in the response parameters, allowing identification of most meaningful variables and elimination of those which are not; understanding and quantifying relationships between inputs, with the possibility to reduce the number of studied variables by implementing cross-relationship functions; further reduction of parameters by usage of dimensionality reduction methods, thus allowing the incorporation of multiple responses into the model selection; definition of the number of models necessary to have in order to model the responses within a certain variance margin; automated selection of a set of models which would accurately represent the distribution of the responses; and/or (6) a possibility to estimate the behavior of a new realization previously not included in initial ensemble.

Furthermore, there is possibility to enhance this through link of external systems: (1) linking the input to Schlumberger products, such as, Petrel, DELFI, Agile Iterative Reservoir Modelling or other tools that enable the creation of a large number of static and/or dynamic reservoir models; and/or (2) connecting the output to Schlumberger products DELFI, RE Workspace, FDPlan, other bespoke tools that would use an ensemble of models for uncertainty, optimization, analysis, decision making.

This is achievable through a combination of data science and artificial intelligence including: (1) innovative visualization techniques incorporated in a decision dashboard; and/or (2) statistical, machine learning and other data science methods which may include dimensionality reduction, clustering, regression using neural networks, decision trees methods etc.

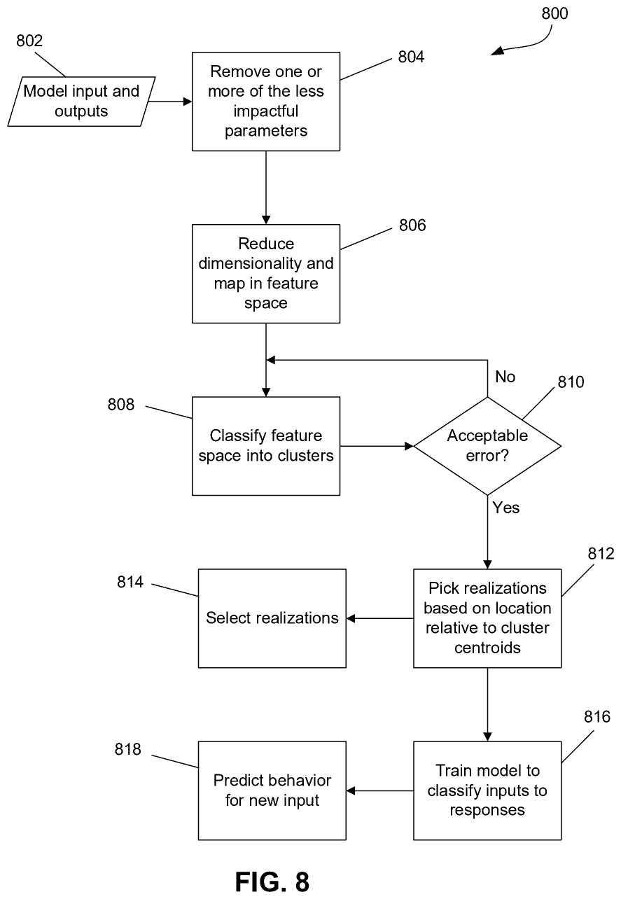

FIG. 8 illustrates a flowchart of a method 800 for selecting a classified subset of representative observations, according to an embodiment. The method 800 may, for example, be configured to constrain the number of observations selected so as to a least (or at least close to the least) number of observations to accurately characterize behavior (e.g., generate a cumulative distribution function) of one or more selected, “meaningful” responses.

The method 800 may include receiving, as input, model inputs and outputs, as at 802. The inputs may include, as noted above, rock properties, fluid properties, reservoir properties, etc. The outputs may include one or more KPIs, as also discussed above.

The method 800 may include removing one or more of the less impactful parameters, as at 804. Such lesser impactful parameters may be determined based on a statistical analysis of the impact that a change in the parameters has on the response. The method 800 may also include reducing the dimensionality to accommodate multiple responses, as at 806. The remaining, vectorized realizations may then be mapped in feature space.

The method 800 may also leverage artificial intelligence, such as, for example, using unsupervised, clustering-based machine learning. For example, the method 800 may include classifying the elements (realizations) mapped in the features pace into clusters, as at 808.

The method 800 may then include determining whether an acceptable error is experienced, as at 810. This may be statistically determined, for example, based on the success of the clustering applied. If the error is not acceptable, the method 800 may return to classifying into clusters and employ different techniques and/or parameters for such clustering.

The method 800 may then proceed to picking realizations based on location relative to cluster centroids, as at 812. For example, one or more realizations that are closest to the centroids may be selected as representative of the cluster, and these realizations may be selected, as at 814, for further uncertainty analysis, e.g., using physical model simulations.

Additionally, the selected and/or other realizations may be employed to train a machine learning model to classify inputs to responses, that is, to predict responses based on a set of inputs, as at 816. For example, results of collection of simulation cases, e.g., in the form of measured inputs and outputs may be fed to the model as training data. Further, simulated outputs from inputs, e.g., in given realizations, may be fed to the model, and thus the model may be trained to predict what response/output would be produced, given a set of model input parameters, as at 818.

By executing the method 800, users may generate a reduced ensemble of realizations and incorporate them into previously prohibitive uncertainty and other types of modelling studies such as field development planning, production and injection forecasting, well placement, history matching, etc. The results (e.g., selected representative reservoir models) can be fed into Well Placement Selection Under Uncertainty method.

### Reservoir Quality Maps/Assessment

Reservoir performance is modeled for future field development planning purposes. Areas with low performance can be investigated for production enhancement, areas without wells can be investigated for infill drilling. However, reaching this understanding includes integrating data from various sources to obtain the best insight.

Reservoir quality maps may be built from reservoir properties such as permeability, net-to-gross ratio, porosity, hydrocarbon volumes in place, and these can take various names such as maps of reservoir quality index, simulation opportunity index, reservoir opportunity index etc. The maps are derived from reservoir models subject to uncertainty and simulation studies to identify potential areas for infill drilling.

In an embodiment, a reservoir quality map using reservoir characteristics and hydrocarbon volumes in place, and also historical well performance by analyzing the historical production and injection data of some and/or all wells in the field, their associated log data and core data, and/or possibly information from the reservoir model to build a machine learning model capable of establishing a map of reservoir quality and production performance. The generated map may be used to analyze the performance of existing wells for production enhancement, identify areas for infill drilling, and/or identify areas for additional measurements to improve the understanding of the reservoir through not only the reservoir modeling aspect.

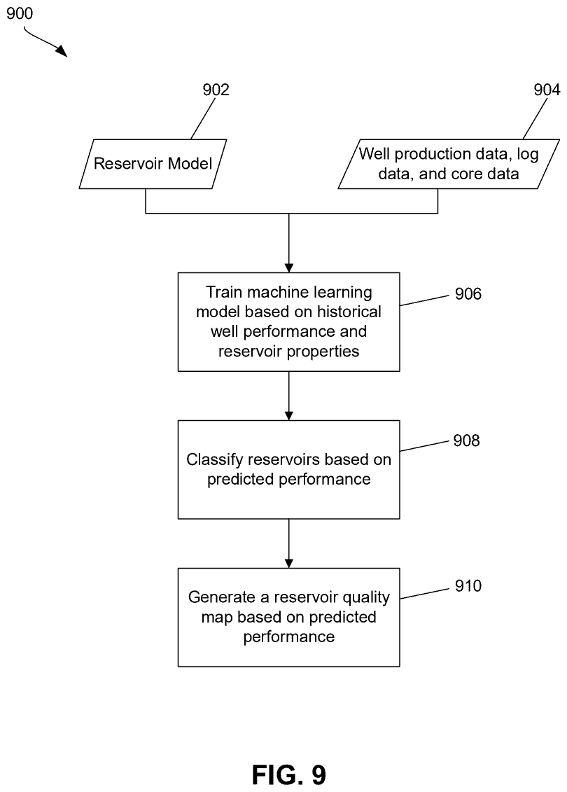

As mentioned above, machine learning techniques may be employed, e.g., for model realization selection in the context of uncertainty analysis and elsewhere. FIG. 9 illustrates an example of one type of machine learning method that may be used, showing a flowchart of a method 900 for building a machine learning model to generate reservoir quality map. The method 900 may receive, as input, a reservoir model representing a subsurface volume or other rock properties, as at 902. The method 900 may also receive, as input, reservoir data, also representing the subsurface volume or rock properties, as at 904, such as well measurement data, such as production and injection history (e.g. rates, volumes produced, pressures), well location (e.g. distance to injectors, distance to other production wells), log data and core data providing insights on reservoir properties (e.g. permeability, porosity, saturation, pressure), and/or reservoir properties derived from the reservoir model when measured data is lacking.

The machine learning model may be trained, as at 906, to create a map of reservoir quality based on the information from well performance and reservoir quality. The quality of the remaining of the reservoir can be evaluated using the machine learning based on the reservoir properties based on the predicted performance.

The method 900 may thus include implementing such a trained model, as at 908, e.g., to classify reservoirs based on predicted performance. Outlier wells may be identified and may potentially be wells requiring production enhancement, areas without wells and flagged with good performance can be targeted for infill drilling where data acquisition can be performed to confirm the model prediction and improve the reliability of the machine learning model. Because machine learning methods integrating both reservoir properties and historical well performance may be used, thus enabling integration of the well performance in the identification of reservoir quality. This allows for the identification of poor well performers as candidate for production enhancement, perform well placement location optimization, and/or identify areas requiring further data acquisition. Accordingly, the method 900 may also include generating a reservoir quality map based on the predicted performance, as at 910. This method can be used as an alternative method of selecting “hot spots” in Well Placement Selection Under Uncertainty method.

### Well Placement Selection Under Uncertainty

Production in an oil field can be increased by improving the performance of existing wells or by drilling additional wells. The performance of the new wells drilled may depend on the location in the reservoir where they are drilled; that is, even in a given reservoir, certain well placements, trajectories, and other parameters may yield better production performance than others.

To locate the potential areas within the reservoir to drill such new wells, engineers may rely on reservoir simulation models to identify the areas where the most oil volume remains with favorable pressure and reservoir rock quality to facilitate hydrocarbon extraction. Reservoir simulation model quality and the quality of the model calibration, if applicable, may play impact the accuracy of such identification. Additionally, to identify which areas identified would lead to favorable production performance, multiple simulation scenarios are generally evaluated to determine the potential performance for each individual area.

Probability maps may be built, which include identified “hot spots” in the reservoir through a probabilistic approach. Such probabilistic approaches may proceed by simulation of physics models, e.g., without assistance from artificial intelligence or production data analysis. By evaluating the potential areas for well placement by analyzing the historical production data of all wells in the field, the associated log data and core data, and/or, in some embodiments, information from the reservoir model to build a machine learning model configured to classify the hot spots, e.g., as discussed above, into reservoir properties leading to gradations of production potential (e.g., numerical scales, qualitative “good”, “poor”, “medium” scores, etc.). The baseline for such potential grades may be historical wells, comparison to which may be used for ranking and selection of candidate wells.

Classifying the hotspots based on actual, historical performance data associated with the identification of potential areas (“hot spots”) within the reservoir to drill new wells can improve the confidence of the area selection, reduce the time taken to evaluate which areas have a better potential for production since each area would not need to be tested beforehand through reservoir simulation, and/or enable better decision making in field development planning.

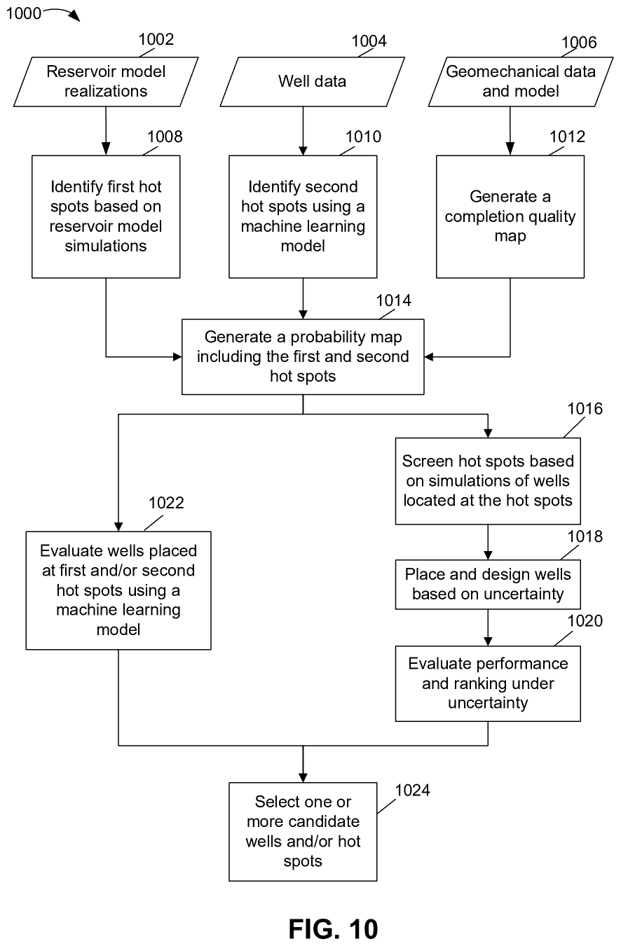

Turning to the illustrated embodiments, FIG. 10 illustrates a flowchart of a method 1000 for drilling a well, e.g., based on a selection of a location for the well, according to an embodiment. The method 1000 may receive, as input, an ensemble of reservoir model realizations, as at 1002. As discussed above, the realizations may be a representative subset of the model realizations that are available based on an uncertainty analysis, with, for example, the representative subset being selected using a machine learning model. Further, the method 1000 may receive well data as input, at 1004. The well data may be measured characteristics of the well, including production history, log data, core data, and/or any other data. In at least one embodiment, the method 1000 may also include receiving geomechanical data (e.g., stress, strain, Poisson's ratio, etc.) for the subsurface, which may be presented, e.g., as a geomechanical model, as at 1006.

From the ensemble of simulations generated through uncertainty analysis, an opportunity index may be calculated based on reservoir properties (e.g., rock properties, fluid saturations, pressure) for each realization. A probability that the opportunity is above a given threshold may be calculated considering the ensemble of opportunity index generated, and/or the areas of higher probability are considered as “hot spots” for drilling. These areas are potentially good quality rock with good hydrocarbon reserves remaining. Accordingly, the method 1000 may include identifying these as one or more “first” hot spots, again, based on the physical reservoir model simulations, as at 1008.

The well data may be employed to identify one or more “second” hot spots, as at 1010. A machine learning model may be built to link well measurement data such as production and injection history (e.g., rates, volumes produced, pressures), well location (e.g., distance to injectors, distance to other production wells), log data and/or core data providing insights on reservoir properties (e.g., permeability, porosity, saturation, pressure), and/or reservoir properties derived from the reservoir model when measured data is lacking. The machine learning model may derive a relationship between reservoir properties/quality and production performance. The first and second hot spots may not be mutually exclusive, but may, in at least some embodiments be overlapping or the same. For example, at least some of the first hot spots may identify the same locations as at least some of the second hot spots. In other embodiments, the first and second hot spots may not refer to any of the same locations.

Additionally, a completion quality map may be generated, as at 1012, using a mechanical earth model to assess the quality of completions (e.g., conventional completions, hydraulic fractures, etc.). Accordingly, the completion quality may be employed to further strengthen the identification of hot spots and/or to identify separate hot spots.

Resulting hot spots identified from the reservoir simulations, the machine learning, and/or the geomechanical model may be employed to generate a probability map, as at 1014. The probability map may be two or three dimensional and may represent at least a portion of the subsurface volume. The probability map may be visualized, e.g., including different colors or other identifications of the hot spots to facilitate reference thereto by one or more operators.

The first and/or second hot spots may then be evaluated. In particular, as at 1016, hypothetical “candidate wells” may be located at the hot spots and then the reservoir. Further, well trajectory design techniques may be implemented to design suitable wells at the hot spots, as at 1018. The reservoir may then be simulated with the candidate wells located at one or more of the hot spots, as at 1020. The simulation may provide a forecast of production (e.g., performance) of the candidate wells at the hot spots, and the candidate wells may then be ranked or otherwise ordered, e.g., based on production, drilling risk, expense, rate of return, etc.

In some embodiments, another machine learning model may be implemented, e.g., instead of or in addition to the simulation at 1016. For example, as at 1022, well placement location can be selected through a machine learning model trained to link well and reservoir parameters to production performance. As discussed above, such machine learning models may be trained using historical performance data, modeled/simulated data, or a combination thereof. An example of such a machine learning implementation is provided below.

Additionally, injection well placement can be incorporated at a varying distance from the production wells to identify candidate injection wells and their configurations that will contribute to enhance production further.

Further, in at least some embodiments, both simulating and machine-learning prediction may be employed to forecast well production. Machine-learning well production forecast can rapidly screen all identified hotspots and eliminate poor areas from further iterations using the reservoir simulation. Integrating multiple techniques/sources of production forecasting may improve the reliability of the well placement location selection and accelerate the screening process by integrating multiple data sources (e.g., reservoir simulation model, historical well performance, geomechanical considerations, drilling risks) in the selection process. The method 1000 may then proceed to selecting one or more of the candidate wells at the identified first and/or second hot spots, as at 1024. In some embodiments, visualizations of digital models of the subsurface, e.g., including the hot spots and the selected candidate wells, may be displayed for a user. The user may interact with the display, e.g., to glean additional information about the candidate well and/or hot spot. Further, the user may employ the generated visualization for drilling activities. In at least one embodiment, a user may construct the selected candidate well based at least in part on the visualization or otherwise based on the selected candidate well.

### Well Performance Forecasts

As noted above, a machine learning model can be used to forecast well performance. Field development planning includes well performance forecasting to assess the future performance of a well and select a development scenario. In an embodiment a methodology using machine learning methods may be used to: (1) predict future performance of an existing producing well; and/or (2) predict performance of an undrilled well at a new location. More particularly, in an embodiment, a well performance forecast may be based on historical well performance data (oil, gas, water production and injection rates and cumulative volumes; bottomhole, tubing head and reservoir pressure) combined with geological properties of the reservoir (e.g. permeability, porosity, saturation, pressure), well location (e.g., distance to producers and injectors), well log and/or core data (e.g., permeability, porosity, saturation, pressure) for conventional reservoirs that may be under primary or secondary recovery processes (e.g. waterflooding).

Through this methodology, future well performance may be predicted without relying on analytical methods, decline curve analysis or numerical methods such as reservoir simulation. The methodology may produce faster results to perform short-term production forecasts, operationalize insights, provide another perspective on performance prediction and/or decision making in the context of field development planning. Advanced machine learning methods (deep learning methods) may integrate different types of data such as time series (oil, gas, water production and injection rates and cumulative volumes; bottomhole, tubing head and reservoir pressure) and tabular data (e.g., geological, petrophysical as described earlier) to predict future performance of existing as well as new wells.

In an embodiment, the workflow may be used to predict future performance of existing wells. The model may continuously learn from continuously updating production data and generate future production profiles for each well in the field using reinforcement learning methods. This will facilitate decision-making process targeted at field development planning such as whether there is a need to drill a new well to meet production target etc.

In an embodiment, the workflow may be used to predict future performance of a new well in the field. The model may continuously learn from continuously updating production data as well as geological data and generate future production profiles for a new well in the field. Fast screening of performance of new wells at different locations will allow to optimize well placement process. This methodology may be integrated with the “Well Placement Selection Under Uncertainty” method discussed above to test out different hotspots generated using probabilistic methods and rank them based on the performance of new wells.

The workflow may be able to produce accurate real-time production forecast for existing wells and production prediction faster and able to screen thousands of locations to generate the most optimal location to drill a well.

In other words, well performance forecast of existing wells may be used to generate “live and evergreen model” that continuously updates and provides up to date well forecasts based on historical data. This data then can then be used to optimize field development planning. Furthermore, well performance forecast of a new well may be used to generate rapid results that allows to screen thousands of well locations to select the most optimal one—complimenting or replacing current technologies used for the same purposes.

### Semi-Supervised Framework for Simultaneous Classification and Prediction of Petrophysical Properties in a 3D Space

In conventional systems and methods, multi-well integrated petrophysical interpretation workflows for 3D static models often include two steps or tasks. A first step may include typing reservoir rock (e.g., reservoir rock typing) from available data (e.g., input data), and a second step may include predicting one or more petrophysical properties (e.g., petrophysical properties prediction) from available data (e.g., input data). It should be appreciated that both steps/tasks may be related. For example, a predicted value of the one or more petrophysical properties may influence an identified or typed reservoir rock. In another example, permeability transform may be a function of the rock type. While both steps/tasks may be closely related, each step is run independently via different workflows and methods. The systems and methods disclosed herein include a workflow that integrates the two steps/tasks into the same or a singular framework or workflow. The workflow may generally loop the cycle to minimize the difference between training and predicted sets for quantitative and/or qualitative features.

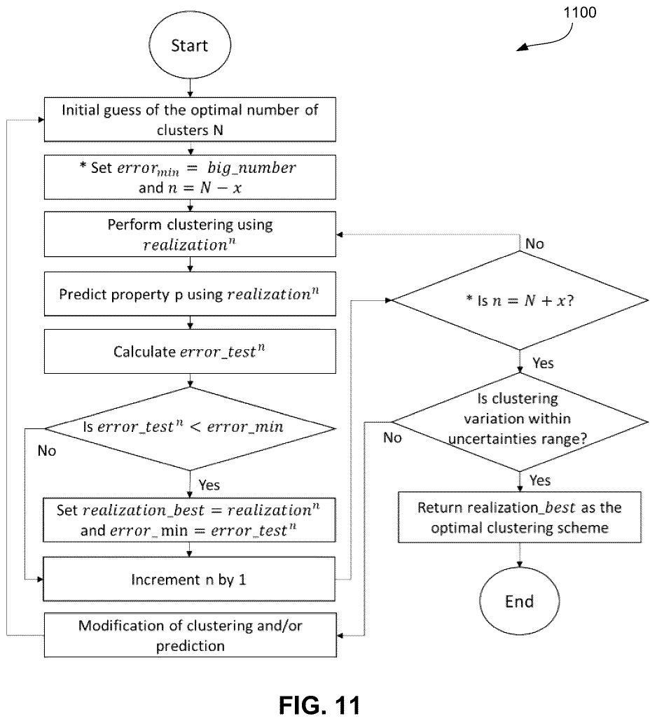

FIG. 11 illustrates an exemplary workflow 1100 for simultaneous classification and prediction of petrophysical properties in a 3D space, according to an embodiment. The workflow 1100 may embed classification and regression (prediction) tasks conventionally solved separately and iteratively. The workflow 110 may allow a system to run multiple realizations of classification followed by prediction, selection of the best scenario from all realizations, and its quality check by re-classification using predicted features instead of the original. If the difference between the two classifications is acceptable, the training model may be saved and utilized for prediction. If the difference between two classifications is not acceptable, the workflow may be looped back with adjustments to one or more parameters. In at least one embodiment, the workflow 1100 may run a clustering workflow for a training dataset for a different number of clusters. For each number of clusters, the workflow may run a prediction workflow for petrophysical property prediction(s). The workflow may then select ‘N’ number of clusters based on the best prediction results. The workflow may then re-run clustering for ‘N’ identified clusters replacing training the training set by the predicted results. The workflow may then identify the difference and modify and/or add new cluster(s). The workflow may then iterate until the prediction results are satisfactory (e.g., above a threshold level and/or the prediction uncertainty is within a defined range, which may be a user defined range).

As illustrated in FIG. 11, the workflow may include receiving input data, which may be or include, but is not limited to, one or more training sets. The training set may include data values or training values. The training set may be or include, but is not limited to, one or more of core data or values, wellbore log data or values, or a combination thereof. The training set may be obtained from one or more inputs. For example, varying cases may be utilized. In another example, varying inputs from each case may be utilized. For example, respective inputs from a first case may be different from respective inputs from a second case, and the inputs from both the first and second cases may be utilized. In at least one embodiment, the input data and/or the training set thereof may be preconditioned. For example, the input data may be cleaned of outliers and organized into a single structured format. In at least one embodiment, each XYZ coordinate number of the features may be present in the single structured format. In at least one embodiment, a feature selection algorithm may be utilized to automatically discard one or more irrelevant features.

The workflow 1100 may include determining a clustering scheme based on the input data. Determining the clustering scheme may include determining one or more clustering parameters based on the input data. Determining the clustering scheme may include utilizing an Akaike Information Criterion (AIC) and/or a Bayesian Information Criterion (BIC). The AIC and/or BIC may be capable of or configured to determine an initial guess or value of a number of clusters from the input data or the training set thereof. In at least one embodiment, the workflow 1100 may include clustering the input data and/or the training set thereof. The number of clusters may be utilized, at least in part, for clustering the input data. For example, based on the AIC and/or the BIC analysis, clustering may be run for N−x to N+x numbers of clusters, where x may be a function of AIC slopes and/or BIC slopes. The number of clusters or the clustering may be utilized to determine a realization prediction. Each realization prediction may include predicted values. Each realization prediction may be run for a targeted feature or targeted property. Illustrative targeted features or properties may be or include, but are not limited to, a formation property prediction, a wellbore log prediction, or the like, or any combination thereof. For example, a realization prediction may be run to determine predicted values for a formation property prediction. In another example, a realization prediction may be run to determine predicted values for a wellbore log prediction.

The workflow 1100 may also include determining a representative or best realization or a best realization prediction. The best realization may be determined by comparing the input data or original training values of the training set and the predicted values of the realization prediction. Determining the best realization may include an error test. Determining the best realization may also include comparing the error test with an error minimum. The best realization may also be determined based on the error minimum, the error test, or a combination thereof. As illustrated in FIG. 11, if the error test is less than the error minimum, then the associated realization may be the best realization prediction, as at 1116. As further illustrated in FIG. 11, if the error test is not less than the error minimum, then ‘n’ may be incremented by 1.

The workflow 1100 may also include clustering the realization prediction (e.g., best realization prediction). For example, the workflow 1100 may include clustering the predicted values of the realization prediction. The clustering may be conducted using the same clustering scheme and/or parameters as at 1106. For example, the clustering of predicted values of the realization prediction may be conducted using the same clustering scheme and/or parameters of the input data.

The workflow 1100 may also include determining if the clustering variations are within uncertainty and uncertainty ranges. For example, the workflow 1100 may also include comparing the clustering of the realization prediction, as determined at 1120, with the clustering of the training values of the training set, as determined at 1106. Comparing the clustering of the realization prediction with the clustering of the training set, as at 1114, may include determining a difference between the clustering of the realization prediction and the clustering of the training set. The difference between the clustering of the realization prediction and the clustering of the training set may be represented by a value or a series of values. Comparing the clustering of the realization prediction with the clustering of the training set may also include determining if the difference between the clustering of the realization prediction and the clustering of the training set is at, above, or below a threshold value or level (e.g., within uncertainty and uncertainty ranges). If the difference is acceptable, such as above the threshold level, the clustering of the realization prediction and the prediction models thereof may be saved for further or future use. If the difference is not acceptable, such as below the threshold level, analysis of the clustering of the realization prediction may be conducted to determine and/or identify whether the clustering scheme and/or parameters should be modified or whether some features should be included or excluded from the input data or the training set thereof. Analyzing the clustering, the clustering scheme, and/or the clustering parameters, may include or utilized domain expert review and/or analysis. Analyzing the clustering, the clustering scheme, and/or the clustering parameters, as at 1126, may also include utilizing sensitivity analysis and/or other techniques.

In at least one embodiment, there may be a link between Permeability Prediction and the Static Rock Types steps which, as discussed above, are performed independently in the conventional system. However, implementation of the conventional system leads to serious contradiction: (1) by definition, the Rock Type should have similar porosity—permeability relationship for all samples; (2) if permeability is predicted for the whole data, it is likely to be averaged for different Rock Types; and (3) averaged permeability values definitely influence Rock Typing results if utilized in this step. However, the framework or workflow disclosed herein may be applied for prediction of different (not only) permeability properties. More particularly, in an embodiment, an iterative simultaneous solution for prediction of quantitative and qualitative petrophysical characteristics and possible solution for a common problem where prediction of one characteristic utilizes a knowledge about another is shown.

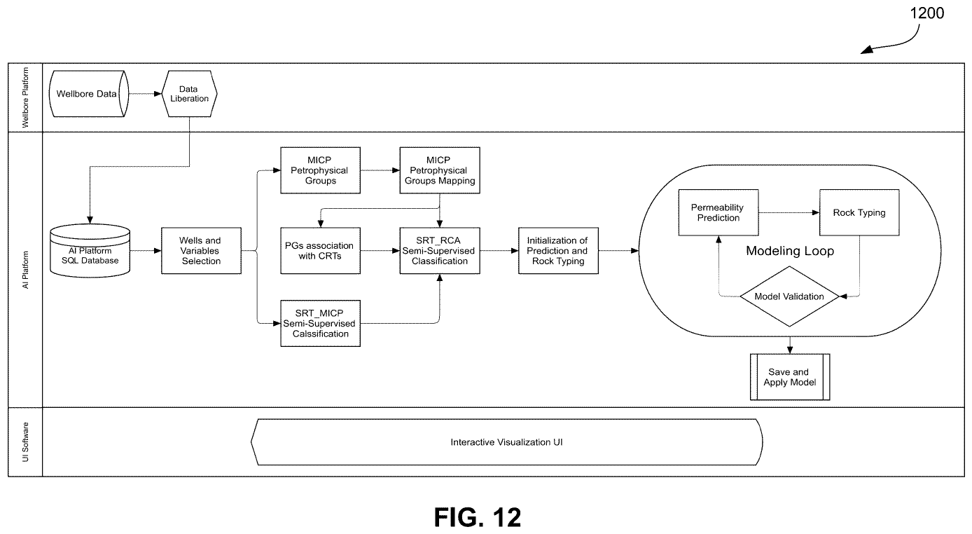

FIG. 12 illustrates an exemplary machine-learning driven workflow 1200 for rocky typing and permeability prediction, according to an embodiment. It should be appreciated that the term SQL refers to a structured query language, and the term AI refers to Artificial Intelligence. The workflow 1200 includes grouping sets of applications to provide a user with tools to complete rock typing at core and log levels. The workflow 1200 also groups sets of applications to predict permeability for non-core wells and intervals. The well data includes logs and the core is liberated from the wellbore platform to a central solution for the design, deployment, and management of AI applications. It should be appreciated that all data may be quality controlled and corrected. Depending on the data available and the respective quality, the workflow 1200 may start with a different module and follow a different path. Generally, the workflow 1200 may start with static rock types (SRT) definitions from capillary pressure curves and candidate rock types (CRT) from core and thin section descriptions using either an SRT_MICP semi-supervised approach or an independent Petrophysical Groups (PG) identification from capillary pressure curves and their association with CRTs. Identified SRT_MICP may be propagated to conventional core analysis (porosity and permeability) to create SRT_RCA. Two next modules may serve to propagate SRT to log domain and estimate permeability for non-cored wells and intervals. Initialization of prediction and rock typing may generate first assumption of a modeled permeability and rock types at the log level, which may be inputs to the Modeling Loop that iteratively performs Permeability Prediction, Rock Typing, and Model Validation to create prediction and classification models that, upon the model validation step, may be passed and saved, and may subsequently be applied to the whole data.

The first step in the workflow may include identifying one or more petrophysical groups (PG) using extracted parameters from capillary pressure, along with porosity and permeability of the samples. To complete the classification of the samples, a Gaussian Mixture Model may be implemented. The number of clusters for classification may be estimated automatically, and the user may have the possibility to modify it along with input parameters for classification before finalizing the results. Single-and bi-modal samples may be classified separately, creating separate PGs. Even if each have similar porosity and permeability distributions, their capillary pressure profiles may be quite different, leading to different saturations at the same height above the free water level. However, because it may be difficult to distinguish single-and bi-modal groups overlaying in the 2D porosity-permeability space, they may be mapped together into a single rock type for the next classification steps. However, it should be appreciated that information about different PGs is not lost, and they may be recognized in the later steps of the Saturation Height Model application.

As illustrated in FIG. 12, the workflow 1200 may include a Modeling Loop, which may be a Permeability Prediction and Rock Typing Loop. The Permeability Prediction and Rock Typing Loop may be organized in such a way that a permeability prediction may be carried out by defined Static Rock Types (SRT), assuming that each SRT has a different porosity-permeability relationship. At each iteration, permeability may be predicted by SRTs, and the final permeability may be estimated as a weighted sum of these permeabilities, with the weight determined from the probability of an SRT definition for a given sample. The newly predicted permeability may then be used for SRTs re-classification, and the prediction may be repeated using the new SRTs.

In the Permeability Prediction and Rock Typing Loop, any algorithm may be utilized, including, but not limited to, Random Forest, Gradient Boosted Trees, and AdaBoost. The core principle of AdaBoost may be to fit a sequence of weak learners (models that are only slightly better than random guessing, such as small decision trees) on repeatedly modified versions of the data. The predictions from all of them are then combined through a weighted majority vote (or sum) to produce the final prediction. At each boosting iteration, the data modifications consist of applying weights to each of the training samples. Initially, these weights are all set to 1/number of samples, so the first step simply trains a weak learner on the original data. For each successive iteration, the sample weights may be individually modified, and the learning algorithm may be reapplied to the reweighted data. At each step, training examples that were incorrectly predicted by the boosted model induced at the previous step may have their weights increased, whereas the weights may be decreased for those that were predicted correctly. As iterations proceed, examples that may be difficult to predict receive ever-increasing influence. Each subsequent weak learner may be thereby forced to concentrate on the examples that were missed by the previous ones in the sequence.

The Modeling Loop may be organized so that in the first iteration, decision trees may be developed until reaching X% of the total sample split, i.e., it will produce one common answer on the predicted variable for X/2% of the samples. This way, the Loop may provide a very broad prediction but for a large number of samples. In the next iteration, the minimal sample split may be reduced by a factor of two, providing a narrowed solution, and so on. The Loop may continue until user-set KPIs are satisfied, or the maximum number of iterations is reached. Once the training Loop is finished, the model may be saved and may be applied to the complete dataset. At this stage, together with the predicted permeability, its P10 and P90 values may be extracted for each sample from the distribution of the results, and corresponding rock types may be estimated.

### Exemplary Method

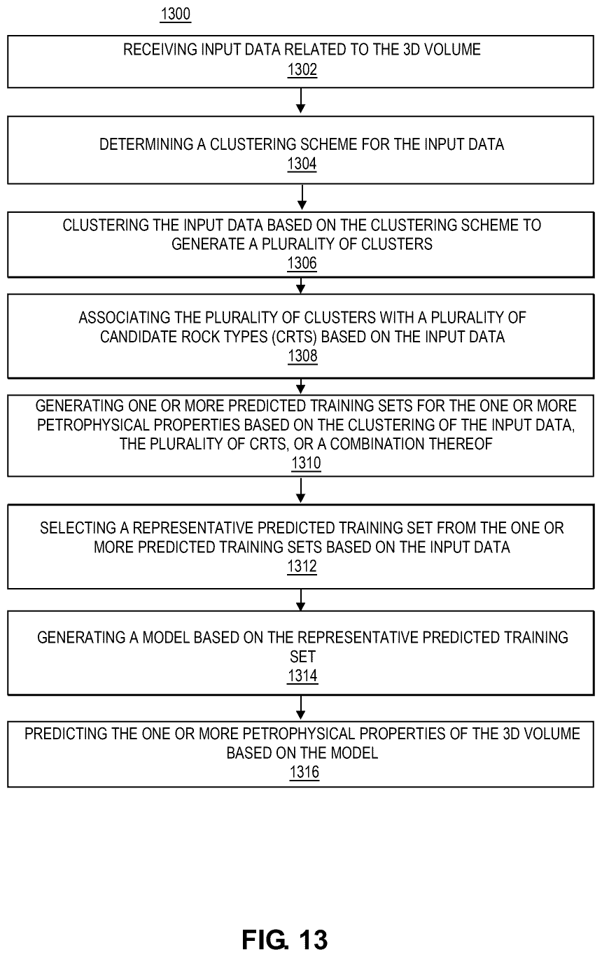

FIG. 13 illustrates a flowchart of a method 1300 for predicting one or more petrophysical properties of a three-dimensional (3D) volume, according to an embodiment. An illustrative order of the method 1300 is provided below; however, one or more portions of the method 1300 may be performed in a different order, simultaneously, repeated, or omitted. At least a portion of the method 1300 may be performed using a computing system.

The method 1300 may include receiving input data related to the 3d volume, as at 1302. The input data may include a training set. The training set may include wellbore data, log data, core data, zonation, index data, core datasets, extracted parameters from capillary pressure profiles, porosity of samples, permeability of samples, or a combination thereof. The training set may be obtained from a plurality of inputs. The training set may include training values. The input data may be preconditioned.

The method 1300 may include determining a clustering scheme for the input data based on the input data, as at 1304. The clustering scheme may include an unsupervised clustering scheme. Determining the clustering scheme may include determining a number of clusters based on the input data. The number of clusters may be based on the training set. The number of clusters may be based on one or more of the extracted parameters from capillary pressure, the porosity of samples, the permeability of samples, or a combination thereof, of the training set. Determining the number of clusters may include utilizing one or more statistical measures. The one or more statistical measures may include an Akaike Information Criterion (AIC), a Bayesian Information Criterion (BIC), or a combination thereof.

The method 1300 may include clustering the input data based on the clustering scheme to generate a plurality of clusters, as at 1306. Each cluster of the plurality of clusters may represent a respective petrophysical group of one or more petrophysical groups.

The method 1300 may include associating the plurality of clusters with a plurality of candidate rock types (CRTS) based on the input data, as at 1308. Associating each cluster of the plurality of clusters may include associating each petrophysical group of the one or more petrophysical groups with the respective CRT of the CRTs.

The method 1300 may include generating one or more predicted training sets for the one or more petrophysical properties based on the clustering of the input data, the plurality of CRTS, or a combination thereof, as at 1310. The predicted training set may include predicted log data, predicted wellbore data, predicted core data, or a combination thereof. The one or more petrophysical properties may include one or more of density, permeability, rock type, or a combination thereof. Each of the predicted training sets may include respective predicted values. Generating the one or more predicted training sets may include training a respective machine learning model for each petrophysical property of the one or more petrophysical properties based on the clustering of the input data. Generating the one or more predicted training sets may include generating a respective predicted training set for each petrophysical property of the one or more petrophysical properties using the respective machine learning model.

The method 1300 may include selecting a representative predicted training set from the one or more predicted training sets based on the input data, as at 1312. Selecting the representative predicted training set may include comparing the representative predicted training set with the input data. Selecting the representative predicted training set may include comparing the respective predicted values of the representative predicted training set with the training values of the input data. Selecting the representative predicted training set may include determining an error test, an error minimum, or a combination thereof of the training values, of the input data and the respective predicted values of the representative predicted training set. Selecting the representative predicted training set may include determining the error minimum between the training values of the input data and the respective predicted values of the representative predicted training set. Selecting the representative predicted training set may also include comparing the error minimum with a threshold value.

The method 1300 may include generating a model based on the representative predicted training set, as at 1314. Generating the model may include determining a predicted permeability based on the representative predicted training set. Generating the model may also include determining a predicted rock-type based on the predicted permeability. Generating the model may also include validating the predicted permeability and the predicted rock-type based on one or more key performance indicators (KPIs). Validating the predicted permeability and the predicted rock-type may include clustering the representative predicted training set based on the model. Clustering the predicted training set may include clustering the respective predicted values of the predicted training set. Validating the predicted permeability and the predicted rock-type may also include comparing the clustering of the representative predicted training set with the clustering of the input data. Comparing the clustering of the representative predicted training set with the clustering of the input data generates a difference value or a series of difference values. Generating the model may also include updating one or more parameters of the model based on the predicted permeability, the predicted rock-type, the one or more KPIs, or a combination thereof. Generating the model may also include generating the model based on the predicted permeability, the predicted rock-type, the one or more KPIs, or a combination thereof.

The method 1300 may include classifying and predicting the one or more petrophysical properties of the 3D volume based on the model, as at 1316.

### Computing Environment

In one or more embodiments, the functions described can be implemented in hardware, software, firmware, or any combination thereof. For a software implementation, the techniques described herein can be implemented with modules (e.g., procedures, functions, subprograms, programs, routines, subroutines, modules, software packages, classes, and so on) that perform the functions described herein. A module can be coupled to another module or a hardware circuit by passing and/or receiving information, data, arguments, parameters, or memory contents. Information, arguments, parameters, data, or the like can be passed, forwarded, or transmitted using any suitable means including memory sharing, message passing, token passing, network transmission, and the like. The software codes can be stored in memory units and executed by processors. The memory unit can be implemented within the processor or external to the processor, in which case it can be communicatively coupled to the processor via various means as is known in the art.

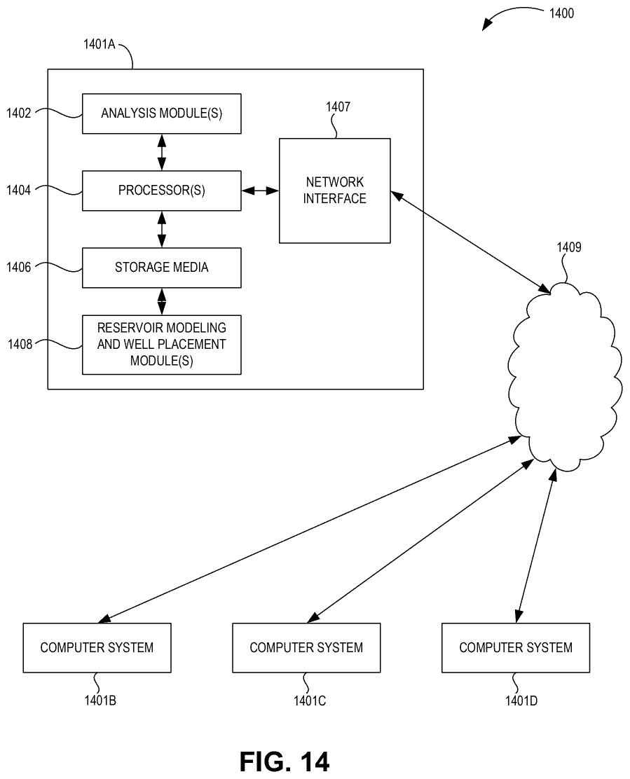

In some embodiments, any of the methods of the present disclosure may be executed by a computing system. FIG. 14 illustrates an example of such a computing system 1400, in accordance with some embodiments. The computing system 1400 may include a computer or computer system 1401A, which may be an individual computer system 1401A or an arrangement of distributed computer systems. The computer system 1401A includes one or more analysis module(s) 1402 configured to perform various tasks according to some embodiments, such as one or more methods disclosed herein. To perform these various tasks, the analysis module 1402 executes independently, or in coordination with, one or more processors 1404, which is (or are) connected to one or more storage media 1406. The processor(s) 1404 is (or are) also connected to a network interface 1407 to allow the computer system 1401A to communicate over a data network 1409 with one or more additional computer systems and/or computing systems, such as 1401B, 1401C, and/or 1401D (note that computer systems 1401B, 1401C and/or 1401D may or may not share the same architecture as computer system 1401A, and may be located in different physical locations, e.g., computer systems 1401A and 1401B may be located in a processing facility, while in communication with one or more computer systems such as 1401C and/or 1401D that are located in one or more data centers, and/or located in varying countries on different continents).

A processor can include a microprocessor, microcontroller, processor module or subsystem, programmable integrated circuit, programmable gate array, or another control or computing device.

The storage media 1406 can be implemented as one or more computer-readable or machine-readable storage media. Note that while in the example embodiment of FIG. 14 storage media 1406 is depicted as within computer system 1401A, in some embodiments, storage media 1406 may be distributed within and/or across multiple internal and/or external enclosures of computing system 1401A and/or additional computing systems. Storage media 1406 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In some embodiments, computing system 1400 contains one or more reservoir modeling and well placement module(s) 1408. In the example of computing system 1400, computer system 1401A includes the reservoir modeling and well placement module 1408. In some embodiments, a single reservoir modeling and well placement module may be used to perform some or all aspects of one or more embodiments of the methods. In alternate embodiments, a plurality of reservoir modeling and well placement modules may be used to perform some or all aspects of methods.

It should be appreciated that computing system 1400 is only one example of a computing system, and that computing system 1400 may have more or fewer components than shown, may combine additional components not depicted in the example embodiment of FIG. 14, and/or computing system 1400 may have a different configuration or arrangement of the components depicted in FIG. 14. The various components shown in FIG. 14 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are all included within the scope of protection of the invention.

Geologic interpretations, models and/or other interpretation aids may be refined in an iterative fashion; this concept is applicable to embodiments of the present methods discussed herein. This can include use of feedback loops executed on an algorithmic basis, such as at a computing device (e.g., computing system 1400, FIG. 14), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to explain the principles of the invention and its practical applications, to thereby enable others skilled in the art to utilize the invention and various embodiments with various modifications as are suited to the particular use contemplated.

What is claimed is:

1. A method for predicting one or more petrophysical properties of a three-dimensional (3D) volume, the method comprising:
receiving input data related to the 3D volume;
determining a clustering scheme for the input data;
clustering the input data based on the clustering scheme to generate a plurality of clusters;
associating the plurality of clusters with a plurality of candidate rock types (CRTs);
generating one or more predicted training sets for the one or more petrophysical properties based on the plurality of CRTs;
selecting a representative predicted training set from the one or more predicted training sets;
generating a model based on the representative predicted training set; and
predicting the one or more petrophysical properties of the 3D volume based on the model.

2. The method of claim 1, wherein the input data comprises a training set obtained from a plurality of inputs, and wherein the training set comprises training values.

3. The method of claim 1, wherein determining the clustering scheme comprises determining a number of clusters based on the input data.

4. The method of claim 1, wherein each cluster of the plurality of clusters represents a respective petrophysical group of one or more petrophysical groups.

5. The method of claim 4, wherein associating the plurality of clusters with the plurality of CRTs comprises associating each cluster of the plurality of clusters with a respective candidate rock type (CRT) of the plurality of candidate rock types (CRTs), and wherein associating each cluster of the plurality of clusters comprises associating each petrophysical group of the one or more petrophysical groups with the respective CRT of the plurality of CRTs.

6. The method of claim 1, wherein generating the one or more predicted training sets for the one or more petrophysical properties comprises:
training a respective machine learning model for each petrophysical property of the one or more petrophysical properties based on the clustering of the input data; and
generating a respective predicted training set for each petrophysical property of the one or more petrophysical properties using the respective machine learning model.

7. The method of claim 1, wherein selecting the representative predicted training set comprises comparing the representative predicted training set with the input data.

8. The method of claim 1, wherein generating the model comprises:
determining a first petrophysical property of the one or more petrophysical properties based on the representative predicted training set;
determining a second petrophysical property of the one or more petrophysical properties based on the first petrophysical property;
validating the first petrophysical property and the second petrophysical property based on one or more key performance indicators (KPIs); and
generating the model based on the first petrophysical property, the second petrophysical property, the one or more KPIs, or a combination thereof.

9. The method of claim 1, further comprising displaying an output comprising one or more of the model, the one or more petrophysical properties of the 3D volume, the one or more predicted training sets, the representative predicted training set, the clustering scheme, the plurality of clusters, or a combination thereof.

10. The method of claim 1, further comprising performing an action in response to detecting the abnormality, wherein the action comprises generating or transmitting a signal that recommends, instructs, or causes a physical action to occur, wherein the physical action comprises one or more of selecting where to drill a wellbore, drilling the wellbore, varying a weight and/or torque on a drill bit that is drilling the wellbore, determining a location and/or amount of hydrocarbons in a subsurface formation and then varying a drilling trajectory of the wellbore toward the hydrocarbons, varying a concentration and/or flow rate of a fluid pumped into the wellbore, or a combination thereof.

11. A computing system, comprising:
one or more processors; and
a memory system comprising one or more non-transitory computer-readable media storing instructions that, when executed by at least one of the one or more processors, cause the computing system to perform operations for predicting one or more petrophysical properties of a three-dimensional (3D) volume, the operations comprising:
receiving input data related to the 3D volume, wherein the input data comprises a training set obtained from a plurality of inputs, and wherein the training set comprises training values;
determining a clustering scheme for the input data based on the input data, wherein the clustering scheme comprises an unsupervised clustering scheme;
clustering the input data based on the clustering scheme to generate a plurality of clusters, wherein each cluster of the plurality of clusters represents a respective petrophysical group of one or more petrophysical groups;
associating each cluster of the plurality of clusters with a respective candidate rock type (CRT) of a plurality of candidate rock types (CRTs) based on the input data;
generating one or more predicted training sets for the one or more petrophysical properties based on the clustering of the input data, the plurality of CRTs, or a combination thereof;
selecting a representative predicted training set from the one or more predicted training sets based on the input data;
generating a model based on the representative predicted training set; and
predicting the one or more petrophysical properties of the 3D volume based on the model.

12. The computing system of claim 11, wherein generating the one or more predicted training sets for the one or more petrophysical properties comprises:
training a respective machine learning model for each petrophysical property of the one or more petrophysical properties based on the clustering of the input data; and
generating a respective predicted training set for each petrophysical property of the one or more petrophysical properties using the respective machine learning model.

13. The computing system of claim 11, wherein each predicted training set of the one or more predicted training sets comprises respective predicted values, and wherein selecting the representative predicted training set comprises determining an error test, an error minimum, or a combination thereof of the training values of the input data and the respective predicted values of the representative predicted training set.

14. The computing system of claim 11, wherein generating the model comprises:
determining a first petrophysical property of the one or more petrophysical properties based on the representative predicted training set, wherein the first petrophysical property is a predicted permeability;
determining a second petrophysical property of the one or more petrophysical properties based on the predicted permeability, wherein the second petrophysical property is a predicted rock-type;
validating the predicted permeability and the predicted rock-type based on one or more key performance indicators (KPIs);
updating one or more parameters of the model based on the predicted permeability, the predicted rock-type, the one or more KPIs, or a combination thereof; and
generating the model based on the predicted permeability, the predicted rock-type, the one or more KPIs, or a combination thereof.

15. The computing system of claim 14, wherein validating the predicted permeability and the predicted rock-type comprises:
clustering the representative predicted training set based on the model; and
comparing the clustering of the representative predicted training set with the clustering of the input data.

16. A non-transitory computer-readable medium storing instructions that, when executed by one or more processors of a computing system, cause the computing system to perform operations for predicting one or more petrophysical properties of a three-dimensional (3D) volume, the operations comprising:
receiving input data related to the 3D volume, wherein the input data comprises a training set obtained from a plurality of inputs, and wherein the training set comprises training values;
determining a clustering scheme for the input data based on the input data, wherein the clustering scheme comprises an unsupervised clustering scheme, and wherein determining the clustering scheme comprises determining a number of clusters based on the training set;
clustering the input data based on the clustering scheme to generate a plurality of clusters, wherein each cluster of the plurality of clusters represents a respective petrophysical group of one or more petrophysical groups;
associating each cluster of the plurality of clusters with a respective candidate rock type (CRT) of a plurality of candidate rock types (CRTs) based on the input data;
generating one or more predicted training sets for the one or more petrophysical properties based on the clustering of the input data, the plurality of CRTs, or a combination thereof;
selecting a representative predicted training set from the one or more predicted training sets based on the input data;
generating a model based on the representative predicted training set; and
predicting the one or more petrophysical properties of the 3D volume based on the model.

17. The non-transitory computer-readable medium of claim 16, wherein determining the number of clusters comprises utilizing one or more statistical measures, and wherein the one or more statistical measures comprises an Akaike Information Criterion (AIC), a Bayesian Information Criterion (BIC), or a combination thereof.

18. The non-transitory computer-readable medium of claim 17, wherein associating each cluster of the plurality of clusters with the respective CRT of the plurality of CRTs comprises associating each petrophysical group of the one or more petrophysical groups with the respective CRT of the plurality of CRTs.

19. The non-transitory computer-readable medium of claim 16, wherein generating the model comprises:
determining a first petrophysical property of the one or more petrophysical properties based on the representative predicted training set, wherein the first petrophysical property is a predicted permeability;
determining a second petrophysical property of the one or more petrophysical properties based on the predicted permeability, wherein the second petrophysical property is a predicted rock-type;
validating the predicted permeability and the predicted rock-type based on one or more key performance indicators (KPIs), wherein validating the predicted permeability and the predicted rock-type comprises:
clustering the representative predicted training set based on the model; and
comparing the clustering of the representative predicted training set with the clustering of the input data; and
generating the model based on the predicted permeability, the predicted rock-type, the one or more KPIs, or a combination thereof.

20. The non-transitory computer-readable medium of claim 19, wherein generating the model further comprises updating one or more parameters of the model based on the predicted permeability, the predicted rock-type, the one or more KPIs, or a combination thereof.
